(19) United States
(12) Patent Application Publication
(10) Pub. No.: US 2025/0079403 A1
(43) Pub. Date: Mar. 6, 2025

(54) SEMICONDUCTOR PACKAGE

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(73) Assignee: SAMSUNG ELECTRONICS CO., LTD., Suwon-si (KR)

(21) Appl. No.: 18/666,556

(22) Filed: May 16, 2024

(30) Foreign Application Priority Data
Aug. 29, 2023 (KR) 10-2023-0113971

(51) Int. Cl. H01L 25/065; H01L 23/00; H01L 23/31; H01L 23/498

(52) U.S. Cl. CPC H01L 25/0657; H01L 23/3128; H01L 23/49816; H01L 24/08; H01L 24/16; H01L 2224/08146; H01L 2224/08225; H01L 2224/16146; H01L 2224/16225; H01L 2225/06513; H01L 2225/06517; H01L 2924/01013; H01L 2924/01029; H01L 2924/1434; H01L 2924/15311; H01L 2924/182

(57) ABSTRACT

A semiconductor package includes a first semiconductor chip including a first semiconductor substrate, the first semiconductor substrate including an active surface and an inactive surface opposite to each other, a plurality of second semiconductor chips stacked on the first semiconductor chip, each of the plurality of second semiconductor chips including a second semiconductor substrate including an active surface and an inactive surface opposite to each other, a plurality of conductive patterns on the active surface of each second semiconductor substrate of the plurality of second semiconductor chips, and a plurality of bonding pads on the inactive surface of the first semiconductor substrate and on the inactive surface of each second semiconductor substrate of the plurality of second semiconductor chips, where the plurality of bonding pads are respectively connected to the plurality of conductive patterns.

### CROSS-REFERENCE TO RELATED APPLICATION

This application is based on and claims priority under 35 U.S.C. § 119 to Korean Patent Application No. 10-2023-0113971, filed on Aug. 29, 2023, in the Korean Intellectual Property Office, the disclosure of which is incorporated by reference herein in its entirety.

### BACKGROUND

Example embodiments of the disclosure relate to a semiconductor package, and more particularly, to a semiconductor package in which two dies are stacked by wafer-to-wafer bonding (i.e., hybrid bonding).

Electronic devices have become smaller and lighter in response to the rapid development of the electronics industry and the needs of users, and as such, semiconductor packages used therein have also become smaller and lighter. Semiconductor packages may require high integration and high speed. In response to the demand for high integration and high speed of semiconductor packages as described above, semiconductor packages including semiconductor chips stacked have been developed.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package which may have improved structural stability by reducing corrosion occurring between a bonding pad and a conductive pattern and thus may prevent stripping between the bonding pad and the conductive pattern.

Additional aspects will be set forth in part in the description which follows and, in part, will be apparent from the description, or may be learned by practice of the presented embodiments.

According to an aspect of an example embodiment, a semiconductor package may include a first semiconductor chip including a first semiconductor substrate, the first semiconductor substrate including an active surface and an inactive surface opposite to each other, a plurality of second semiconductor chips stacked on the first semiconductor chip, each of the plurality of second semiconductor chips including a second semiconductor substrate including an active surface and an inactive surface opposite to each other, a plurality of conductive patterns on the active surface of the second semiconductor substrate of each of the plurality of second semiconductor chips, and a plurality of bonding pads on the inactive surface of the first semiconductor substrate and on the inactive surface of the second semiconductor substrate of each of the plurality of second semiconductor chips, where the plurality of bonding pads are respectively connected to the plurality of conductive patterns, where each of the plurality of conductive patterns includes an inner conductive pattern, and an outer conductive pattern including a portion between the inner conductive pattern and a respective bonding pad, where the outer conductive pattern includes a first metal that is ionized into an N-valent cation, N being a natural number of 1 or more, and where a reduction potential of the first metal ionized into the N-valent cation is in a range from (−10×N) V to (−0.1567×N) V.

According to an aspect of an example embodiment, a semiconductor package may include a first semiconductor chip including a first semiconductor substrate and a plurality of first through electrodes extending through the first semiconductor substrate, the first semiconductor substrate including an active surface and an inactive surface opposite to each other, a plurality of second semiconductor chips stacked on the first semiconductor chip, each of the plurality of second semiconductor chips including a second semiconductor substrate and a plurality of second through electrodes extending through the second semiconductor substrate including an active surface and an inactive surface opposite to each other, a plurality of conductive patterns on the active surface of the second semiconductor substrate of each of the plurality of second semiconductor chips, and a plurality of bonding pads on the plurality of first through electrodes and the plurality of second through electrodes, where the plurality of bonding pads are respectively electrically connected between the plurality of first through electrodes and the plurality of conductive patterns, and between the plurality of second through electrodes and the plurality of conductive patterns, where each of the plurality of conductive patterns includes a first metal that is ionized into an N-valent cation, N being a natural number of 1 or more, and where a reduction potential of the first metal ionized into the N-valent cation is in a range from (−0.9567×N) V to (−0.1567×N) V.

According to an aspect of an example embodiment, a semiconductor package may include a first semiconductor chip including a first semiconductor substrate and a plurality of first through electrodes extending through the first semiconductor substrate, the first semiconductor substrate including an active surface and an inactive surface opposite to each other, a plurality of second semiconductor chips stacked on the first semiconductor chip, each of the plurality of second semiconductor chips including a second semiconductor substrate and a plurality of second through electrodes extending through the second semiconductor substrate, wherein the second semiconductor substrate of each of the plurality of second semiconductor chips includes an active surface and an inactive surface opposite to the active surface, a plurality of conductive patterns on the active surface of the second semiconductor substrate of each of the plurality of seconds semiconductor chips, the plurality of conductive patterns including aluminum, and a plurality of bonding pads on the inactive surface of the first semiconductor substrate and the inactive surface of the second semiconductor substrate of each of the plurality of second semiconductor chips, wherein the plurality of bonding pads are respectively connected to the plurality of conductive patterns, each of the plurality of conductive patterns includes an inner conductive pattern including copper and an outer conductive pattern covering a sidewall of the inner conductive pattern and a lower surface of the inner conductive pattern, the outer conductive pattern includes a first metal that is ionized into an N-valent cation, N being a natural number of 1 or more, and a reduction potential of the first metal is in a range of (−0.9567×N) V to (−0.1567×N) V.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1A is a cross-sectional view illustrating a semiconductor package according to one or more example embodiments;

FIG. 1B is an enlarged view of portion EX in FIG. 1A according to one or more example embodiments;

FIG. 2A is an enlarged view illustrating a semiconductor package according to one or more example embodiments;

FIG. 2B is an enlarged view illustrating a semiconductor package according to one or more example embodiments; and

FIGS. 3, 4, 5, 6, 7, 8, 9, and 10 are cross-sectional views illustrating a method of manufacturing a semiconductor package, according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

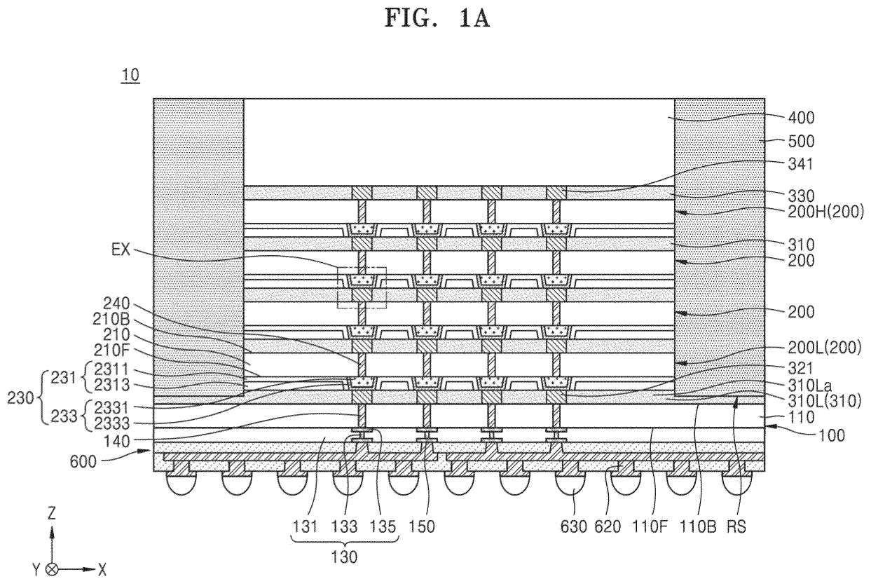

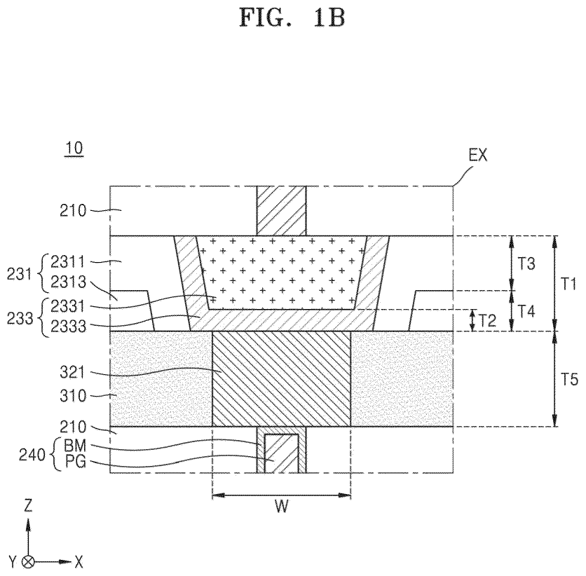

FIG. 1A is a cross-sectional view illustrating a semiconductor package 10 according to one or more example embodiments. FIG. 1B is an enlarged view of portion EX in FIG. 1A according to one or more example embodiments.

Referring to FIGS. 1A and 1B, the semiconductor package 10 may include a first semiconductor chip 100 and a plurality of second semiconductor chips 200. FIG. 1A illustrates that the semiconductor package 10 includes four second semiconductor chips 200, but the semiconductor package 10 is not limited thereto. For example, the semiconductor package 10 may include two or more second semiconductor chips 200. In some embodiments, the semiconductor package 10 may include second semiconductor chips 200 of multiples of 4.

The plurality of second semiconductor chips 200 may be sequentially stacked on the first semiconductor chip 100. For convenience of description, the second semiconductor chip 200, which is located at the lowermost end and located on the first semiconductor chip 100, may be defined as a lowermost second semiconductor chip 200L, and the second semiconductor chip 200 located at the uppermost end may be defined as an uppermost second semiconductor chip 200H.

A direction in which the first semiconductor chip 100 extends may be defined as a first horizontal direction (e.g., the X direction), a direction which crosses the first horizontal direction and in which the first semiconductor chip 100 extends may be defined as a second horizontal direction (e.g., the Y direction), and a direction perpendicular to an upper surface of the first semiconductor chip 100 may be defined as a vertical direction (e.g., the Z direction). In addition, the first horizontal direction may be referred to as the X direction, the second horizontal direction may be referred to as the Y direction, and the vertical direction may be referred to as the Z direction.

The first semiconductor chip 100 may include a first semiconductor substrate 110 having an active surface 110F and an inactive surface 110B opposite to each other, a first individual device arranged on the active surface 110F of the first semiconductor substrate 110, a first wiring structure 130 arranged on the active surface 110F of the first semiconductor substrate 110, and a plurality of first through electrodes 140 connected to the first wiring structure 130 and extending through the first semiconductor substrate 110. The first wiring structure 130 may include a first wiring layer 131, a wiring via 133, and a wiring pattern 135.

The first semiconductor chip 100 may further include a plurality of chip pads 150 arranged on a lower surface of the first semiconductor chip 100 and electrically connected to the first wiring structure 130. The plurality of chip pads 150 may be electrically connected to the wiring via 133 and/or the wiring pattern 135, and may be electrically connected to the first individual device through the wiring via 133 and/or the wiring pattern 135.

Within the semiconductor package 10, the first semiconductor chip 100 may be arranged such that the active surface 110F of the first semiconductor substrate 110 faces downward and the inactive surface 110B faces upward. The active surface 110F of the first semiconductor substrate 110 may be referred to as a lower surface of the first semiconductor substrate 110, and the inactive surface 110B of the first semiconductor substrate 110 may be referred to as an upper surface of the first semiconductor substrate 110.

The second semiconductor chip 200 may include a second semiconductor substrate 210 having an active surface 210F and an inactive surface 210B opposite to each other, a second individual device arranged on the active surface 210F of the second semiconductor substrate 210, a second wiring structure 230 arranged on the active surface 210F of the second semiconductor substrate 210, and a plurality of second through electrodes 240 connected to the second wiring structure 230 and extending through the second semiconductor substrate 210. The second wiring structure 230 may include a second wiring layer 231 and a conductive pattern 233.

Within the semiconductor package 10, the second semiconductor chip 200 may be arranged such that the active surface 210F of the second semiconductor substrate 210 faces downward and the inactive surface 210B faces upward. In other words, the second semiconductor chip 200 may be arranged such that the active surface 210F of the second semiconductor substrate 210 faces the inactive surface 110B of the first semiconductor chip 100.

The first semiconductor substrate 110 and the second semiconductor substrate 210 may include, for example, a semiconductor material such as silicon (Si). Alternatively, the first semiconductor substrate 110 and the second semiconductor substrate 210 may include a semiconductor material such as germanium (Ge). The first semiconductor substrate 110 and the second semiconductor substrate 210 may include conductive regions (for example, wells doped with impurities). The first semiconductor substrate 110 and the second semiconductor substrate 210 may have various device isolation structures such as a shallow trench isolation (STI) structure.

Each of the first individual device and the second individual device may include various types of a plurality of individual devices. The plurality of individual devices may include various types of microelectronic devices, for example, a metal-oxide-semiconductor (MOS) field effect transistor (FET) (MOSFET) such as a complementary MOS (CMOS) transistor, an image sensor such as system large scale integration (LSI) or a CMOS imaging sensor (CIS), a micro-electro-mechanical system (MEMS), an active device, a passive device, and the like.

Each of the first individual device and the second individual device may further include a conductive wire or a conductive plug. The plurality of individual devices, which are included in the first individual device or the second individual device, may be electrically connected to the conductive region of the first semiconductor substrate 110 or the second semiconductor substrate 210 by the conductive wire or the conductive plug. The plurality of individual devices may be electrically isolated from other neighboring individual devices by an insulating layer.

The first semiconductor chip 100 or the second semiconductor chip 200 may be a memory semiconductor chip. In some embodiments, the first semiconductor chip 100 may include a serial-parallel conversion circuit and may be a buffer chip for controlling the plurality of second semiconductor chips 200. Also, the plurality of second semiconductor chips 200 may be memory chips including memory cells. For example, the semiconductor package 10 including the first semiconductor chip 100 and the plurality of second semiconductor chips 200 may be a high bandwidth memory (HBM), and as such, the first semiconductor chip 100 may be referred to as an HBM controller die, and each of the plurality of second semiconductor chips 200 may be referred to as a dynamic random access memory (DRAM) die.

The first wiring structure 130 may include the first wiring layer 131, a plurality of wiring vias 133 extending through a portion of the first wiring layer 131, and a plurality of wiring patterns 135 connected to the plurality of wiring vias 133. In some embodiments, the plurality of wiring vias 133 and the plurality of wiring patterns 135 may be located at different levels in the vertical direction (e.g., the Z direction), and the first wiring structure 130 may have a multilayer wiring structure. When the first wiring structure 130 has the multilayer wiring structure, the first wiring layer 131 may have a multilayer structure in which a plurality of insulating layers are stacked, in correspondence to the multilayer wiring structure.

In some embodiments, the first wiring layer 131 may include an insulating material. For example, the first wiring layer 131 may include silicon oxide, silicon nitride, silicon oxynitride, an insulating material having a lower dielectric constant than silicon oxide, or a combination thereof. In some embodiments, the first wiring layer 131 may include a tetraethyl orthosilicate (TEOS) layer, or an ultralow K (ULK) layer having an ultralow dielectric constant K of about 2.2 to about 2.4. The ULK layer may include an SiOC layer or an SiCOH layer.

In some embodiments, the wiring via 133 and the wiring pattern 135 may include a conductive material. For example, the wiring via 133 and the wiring pattern 135 may include aluminum, copper, or tungsten. In some embodiments, the wiring via 133 and the wiring pattern 135 may include a barrier layer for wiring and a metal layer for wiring. The barrier layer for wiring may include metal, metal nitride, or an alloy. The metal layer for wiring may include at least one metal of W, Al, Ti, Ta, Ru, Mn, and Cu.

The second wiring structure 230 may include the second wiring layer 231 and a plurality of conductive patterns 233 extending through the second wiring layer 231. Each of the plurality of conductive patterns 233 may include an inner conductive pattern 2331 and an outer conductive pattern 2333 covering at least one surface (for example, a lower surface) of the inner conductive pattern 2331.

In some embodiments, the second wiring layer 231 may include an upper wiring layer 2311 and a lower wiring layer 2313. The upper wiring layer 2311 may surround a sidewall of the conductive pattern 233. The upper wiring layer 2311 may conformally extend along a lower surface of the second semiconductor chip 200 and the sidewall of the conductive pattern 233 (i.e., the upper wiring layer 2311 may conformally cover a lower surface of the second semiconductor chip 200 and the sidewall of the conductive pattern 233). The lower wiring layer 2313 may be arranged under the upper wiring layer 2311. The lower wiring layer 2313 may fill a portion of a gap between the second semiconductor chip 200 and a bonding insulating layer 310, which is not filled with the upper wiring layer 2311.

In some embodiments, the second wiring layer 231 may include an insulating material. For example, the second wiring layer 231 may include silicon oxide, silicon nitride, silicon oxynitride, an insulating material having a lower dielectric constant than silicon oxide, or a combination thereof. In some embodiments, the second wiring layer 231 may include a tetraethyl orthosilicate (TEOS) layer, or an ultralow K (ULK) layer having an ultralow dielectric constant K of about 2.2 to about 2.4. The ULK layer may include an SiOC layer or an SiCOH layer. In some embodiments, the upper wiring layer 2311 of the second wiring layer 231 may include a high-density polyethylene layer, and the lower wiring layer 2313 may include a TEOS layer.

The second wiring structure 230 may further include a plurality of sub-wiring patterns located at different levels from the plurality of conductive patterns 233 in the vertical direction (e.g., the Z direction), may include a plurality of sub-wiring vias for electrically connecting the plurality of sub-wiring patterns and the conductive patterns 233 located at the different levels, and may have a multilayer wiring structure. The plurality of sub-wiring vias and the plurality of sub-wiring patterns of the second wiring structure 230 may respectively have similar structures to the plurality of wiring vias 133 and the plurality of wiring patterns 135 of the first wiring structure 130. In some embodiments, the plurality of sub-wiring vias and the plurality of sub-wiring patterns may include a conductive material such as aluminum, copper, or tungsten.

The conductive pattern 233 may have a tapered shape having a horizontal width decreasing from an upper side to a lower side. In other words, the conductive pattern 233 may have the horizontal width decreasing away from the active surface 210F of the second semiconductor substrate 210. A minimum horizontal width of the conductive pattern 233 may be greater than a minimum horizontal width of a bonding pad 321, and the sidewall of the conductive pattern 233 may be spaced apart from a sidewall of the bonding pad 321 (i.e., the sidewalls of the bonding pad 321 may be within the horizontal width of the conductive pattern 233). The sidewall of the conductive pattern 233 may be connected to the sidewall of the bonding pad 321 through a lower surface of the conductive pattern 233. Accordingly, the sidewall of the conductive pattern 233, the lower surface of the conductive pattern 233, and the sidewall of the bonding pad 321 may have a stepped structure.

The inner conductive pattern 2331 may have a tapered shape having a horizontal width decreasing from an upper side to a lower side. In other words, the inner conductive pattern 2331 may have the horizontal width decreasing away from the active surface 210F of the second semiconductor substrate 210. The outer conductive pattern 2333 may conformally extend on a sidewall of the inner conductive pattern 2331 to cover a lower surface of the inner conductive pattern 2331 and cover the sidewall of the inner conductive pattern 2331. Materials, which may be included in the inner conductive pattern 2331 and the outer conductive pattern 2333, are described below.

The first through electrode 140 may be arranged on the first wiring structure 130 to be electrically connected to the wiring via 133 and the wiring pattern 135 of the first wiring structure 130, and the second through electrode 240 may be arranged on the second wiring structure 230 to be electrically connected to the conductive pattern 233 of the second wiring structure 230.

In some embodiments, each of the first through electrode 140 and the second through electrode 240 may be formed of a through silicon via (TSV). Each of the first through electrode 140 and the second through electrode 240 may include a conductive plug extending through each of the first semiconductor substrate 110 and the second semiconductor substrate 210 and a conductive barrier layer surrounding or at least partially surrounding the conductive plug. The conductive plug may have a cylindrical shape, and the conductive barrier layer may have a cylindrical shape surrounding a sidewall of the conductive plug.

For example, as illustrated in FIG. 1B, the second through electrode 240 may include a conductive plug PG and a conductive barrier layer BM, and the conductive barrier layer BM may be arranged to surround a sidewall of the conductive plug PG. Similar to the second through electrode 240, the first through electrode 140 may also include a conductive plug and a conductive barrier layer. The conductive barrier layer BM may include a portion contact the bonding pad 321, and may include a portion positioned between the conductive plug PG and the bonding pad 321.

In some embodiments, the conductive plug PG may include a conductive material such as copper, and the conductive barrier layer BM may include a conductive material such as Ti, Ta, V, Zn, or a combination thereof.

A via insulating layer may be positioned between the first through electrode 140 and the first semiconductor substrate 110 and between the second through electrode 240 and the second semiconductor substrate 210 to surround sidewalls of the first through electrode 140 and the second through electrode 240. The first through electrode 140 and the second through electrode 240 may have any one of a via-first structure, a via-middle structure, and a via-last structure.

The bonding insulating layers 310 may be respectively positioned between the first semiconductor chip 100 and the lowermost second semiconductor chip 200L, and between a plurality of second semiconductor chips 200 adjacent to each other. The bonding insulating layer 310 may be arranged to surround sidewalls of a plurality of bonding pads 321. The bonding insulating layer 310 may have a vertical height of about 100 nanometers to about 3 micrometers. The bonding pad 321 may be at least partially surrounded by the bonding insulating layer 310.

From among a plurality of bonding insulating layers 310, the bonding insulating layer 310 positioned between the first semiconductor chip 100 and the lowermost second semiconductor chip 200L may be referred to as a lowermost bonding insulating layer 310L. The lowermost bonding insulating layer 310L may include a portion 310La overlapping the lowermost second semiconductor chip 200L in the vertical direction (e.g., the Z direction) and a portion not overlapping the lowermost second semiconductor chip 200L in the vertical direction (e.g., the Z direction).

A height in the vertical direction (e.g., the Z direction) of the portion 310La of the lowermost bonding insulating layer 310L, which overlaps the lowermost second semiconductor chip 200L, may be greater than a height in the vertical direction (e.g., the Z direction) of the portion of the lowermost bonding insulating layer 310L, which does not overlap the lowermost second semiconductor chip 200L. In other words, the lowermost bonding insulating layer 310L may include a recess portion RS. Due to the recess portion RS, an upper surface of the lowermost bonding insulating layer 310L may protrude upwards at the portion overlapping the lowermost second semiconductor chip 200L than at the portion not overlapping the lowermost second semiconductor chip 200L.

The lowermost bonding insulating layer 310L may cover a portion of the upper surface of the first semiconductor chip 100, which does not overlap the lowermost second semiconductor chip 200L. The lowermost bonding insulating layer 310L may cover the upper surface of the first semiconductor chip 100, which is not covered by the plurality of bonding pads 321, at the portion of the upper surface of the first semiconductor chip 100 overlapping the lowermost second semiconductor chip 200L.

From among the plurality of bonding insulating layers 310, the remaining bonding insulating layers 310 other than the lowermost bonding insulating layer 310L may cover a portion of the upper surface of the second semiconductor chip 200 that are not covered by the plurality of bonding pads 321.

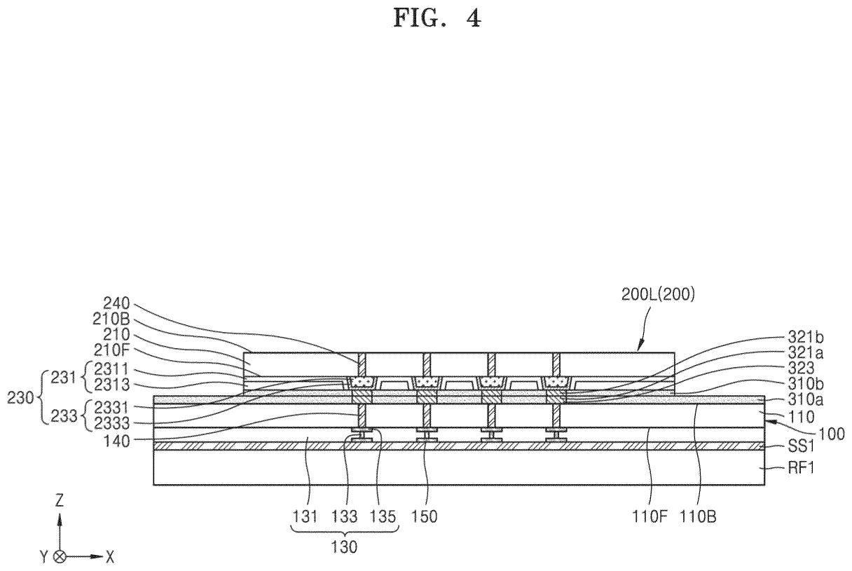

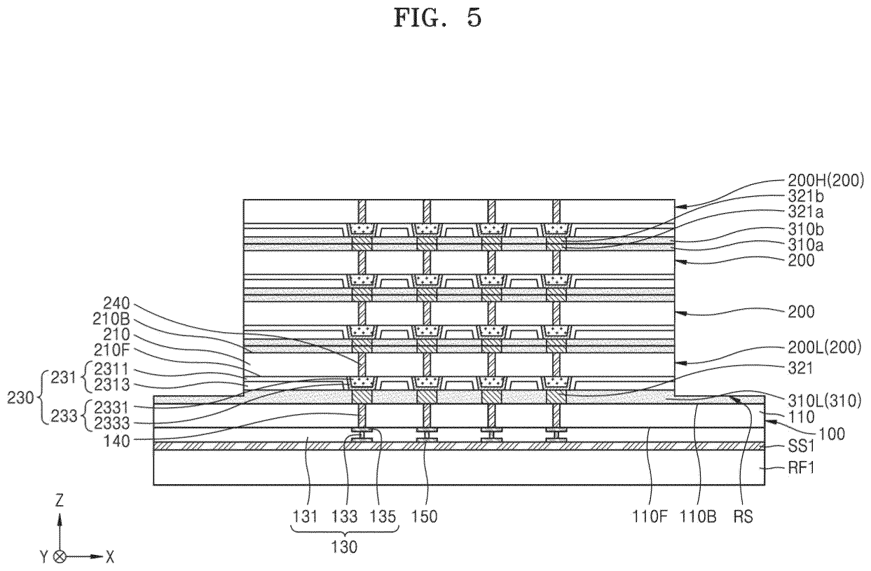

In some embodiments, the bonding insulating layer 310 may be formed via diffusion bonding for respectively forming insulating material layers on the first semiconductor chip 100 and surfaces of two adjacent chips facing each other from among the plurality of second semiconductor chips 200, expanding the insulating material layers by heat to contact each other, and diffusing atoms within the insulating material layers such that the insulating material layers are integrated with each other. A method of forming the bonding insulating layer 310 is described in detail below with reference to FIGS. 4 and 5.

In some embodiments, the bonding insulating layer 310 may include a material capable of diffusion bonding described above. For example, the bonding insulating layer 310 may include any one material from among SiO, SiN, SiCN, SiCO, and a polymer material. The polymer material may be benzocyclobutene (BCB), polyimide (PI), polybenzoxazole (PBO), silicon, acrylate, or epoxy. For example, the bonding insulating layer 310 may include silicon oxide.

The plurality of bonding pads 321 may be arranged on the inactive surface 110B of the first semiconductor substrate 110 and the inactive surface 210B of the second semiconductor substrate 210. The plurality of bonding pads 321 may have, for example, a vertical height of about 100 nanometers to about 3 micrometers. The plurality of bonding pads 321 may be respectively positioned between the first semiconductor chip 100 and the lowermost second semiconductor chip 200L and between a plurality of second semiconductor chips 200 adjacent to each other. The first semiconductor chip 100 and the plurality of second semiconductor chips 200 may be respectively electrically connected through the plurality of bonding pads 321 to exchange signals and provide power and ground.

The plurality of bonding pads 321 may be positioned between the conductive pattern 233 of the second wiring structure 230 and the first through electrode 140, as well as between the conductive pattern 233 of the second wiring structure 230 and the second through electrode 240. The plurality of bonding pads 321 may electrically connect the conductive pattern 233 of the second wiring structure 230 and the first through electrode 140, as well as the conductive pattern 233 of the second wiring structure 230 and the second through electrode 240.

In some embodiments, the bonding pad 321 may be spaced apart from the inner conductive pattern 2331 with a portion of the outer conductive pattern 2333 covering the lower surface of the inner conductive pattern 2331 therebetween. The outer conductive pattern 2333 may include a portion positioned between the bonding pad 321 and the inner conductive pattern 2331, and may electrically connect the bonding pad 321 and the inner conductive pattern 2331.

In some embodiments, the bonding pad 321 may be formed via diffusion bonding for respectively forming conductive material layers on the first semiconductor chip 100 and surfaces of two adjacent chips facing each other from among the plurality of second semiconductor chips 200, expanding the conductive material layers by heat to contact each other, and diffusing metal atoms within the conductive material layers such that the conductive material layers are integrated with each other. The method of forming the plurality of bonding pads 321 is described in detail below with reference to FIGS. 4 and 5.

In some embodiments, the inner conductive pattern 2331 may include aluminum, and the outer conductive pattern 2333 may include a different material from the inner conductive pattern 2331. In some embodiments, the bonding pad 321 may include a material capable of diffusion bonding, such as copper (Cu). A reduction potential of the inner conductive pattern 2331 may be −1.67 V, which is a reduction potential of aluminum. In addition, a reduction potential of the bonding pad 321 may be +0.34 V, which is a reduction potential of copper.

The reduction potential of the inner conductive pattern 2331, a reduction potential of the outer conductive pattern 2333, and the reduction potential of the bonding pad 321 may be different from one another. The reduction potential of the inner conductive pattern 2331 and the reduction potential of the outer conductive pattern 2333 may be lower than the reduction potential of the bonding pad 321. In addition, in some embodiments, the reduction potential of the outer conductive pattern 2333 may have a negative value.

In some embodiments, the outer conductive pattern 2333 may include first metal that may be ionized into a monovalent cation, and a reduction potential of the first metal may be equal to or lower than −0.5567 V. The outer conductive pattern 2333 may include second metal that may be ionized into a divalent cation, and a reduction potential of the second metal may be equal to or lower than −1.113 V. The outer conductive pattern 2333 may include third metal that may be ionized into a trivalent cation, and a reduction potential of the third metal may be equal to or lower than −1.67 V.

In other words, the outer conductive pattern 2333 may include metal that may be ionized into an N-valent cation (N is a natural number of 1 or more), and a reduction potential of the metal, which may be ionized into the N-valent cation, may be equal to or lower than (−0.5567×N) V. Alternatively, the outer conductive pattern 2333 may include metal that may be ionized into an N-valent cation, and a reduction potential of the metal, which may be ionized into the N-valent cation, may be equal to or lower than (−0.5567×N) V. Also, the reduction potential of the metal of the outer conductive pattern 2333 may be higher than (−10×N) V.

For example, when the outer conductive pattern 2333 includes Ti that may be ionized into a divalent cation, the reduction potential of the outer conductive pattern 2333 may be −1.63 V lower than −1.113 V. As another example, when the outer conductive pattern 2333 includes V that may be ionized into a divalent cation, the reduction potential of the outer conductive pattern 2333 may be −1.13 V lower than the −1.113 V.

In some embodiments, a first reduction potential may be formed in an upper region of the bonding pad 321 by a potential difference between the inner conductive pattern 2331 and the outer conductive pattern 2333, and the bonding pad 321. In addition, a second reduction potential may be formed in an intermediate region of the bonding pad 321 by a potential difference between the outer conductive pattern 2333 and the bonding pad 321. The upper region of the bonding pad 321 may include an interface between the bonding pad 321 and the outer conductive pattern 2333 (i.e., an upper surface of the bonding pad 321), and the intermediate region of the bonding pad 321 may include a region excluding the interface between the bonding pad 321 and the outer conductive pattern 2333 (i.e., a region excluding the upper surface of the bonding pad 321).

The first reduction potential formed in the upper region of the bonding pad 321 may be different from the second reduction potential formed in the intermediate region of the bonding pad 321. In detail, the first reduction potential formed in the upper region of the bonding pad 321 may be the same as or lower than the second reduction potential formed in the intermediate region of the bonding pad 321. In other words, a reduction potential of a portion of the bonding pad 321 adjacent to the conductive pattern 233 may be the same as or lower than a reduction potential of a remaining portion of the bonding pad 321.

In some embodiments, the outer conductive pattern 2333 may include first metal that may be ionized into a monovalent cation, and a reduction potential of the first metal may be −0.9567 V to −0.1567 V. The outer conductive pattern 2333 may include second metal that may be ionized into a divalent cation, and a reduction potential of the second metal may be −1.9134 V to −0.3134 V. The outer conductive pattern 2333 may include third metal that may be ionized into a trivalent cation, and a reduction potential of the third metal may be −2.8701 V to −0.4701 V.

In other words, the outer conductive pattern 2333 may include metal that may be ionized into an N-valent cation (N is a natural number of 1 or more), and a reduction potential of the metal, which may be ionized into the N-valent cation, may be (−0.9567×N) V to (−0.1567×N) V. Alternatively, the outer conductive pattern 2333 may include metal that may be ionized into an N-valent cation, and a reduction potential of the metal, which may be ionized into the N-valent cation, may be (−0.9567×N) V to (−0.1567×N) V.

For example, when the outer conductive pattern 2333 includes Zn that may be ionized into a divalent cation, a reduction potential of the outer conductive pattern 2333 may have a value of −0.76 V included in a range of −1.9134 V to −0.3134 V.

In some embodiments, a first reduction potential may be formed in the upper region of the bonding pad 321 by a potential difference between the inner conductive pattern 2331 and the outer conductive pattern 2333, and the bonding pad 321. In addition, a second reduction potential may be formed in the intermediate region of the bonding pad 321 by a potential difference between the outer conductive pattern 2333 and the bonding pad 321. The upper region of the bonding pad 321 may include an interface between the bonding pad 321 and the outer conductive pattern 2333 (i.e., the upper surface of the bonding pad 321), and the intermediate region of the bonding pad 321 may include a region excluding the interface between the bonding pad 321 and the outer conductive pattern 2333 (i.e., a region excluding the upper surface of the bonding pad 321).

The first reduction potential formed in the upper region of the bonding pad 321 may be different from the second reduction potential formed in the intermediate region of the bonding pad 321. The first reduction potential formed in the upper region of the bonding pad 321 may have a value between the second reduction potential −0.4 V formed in the intermediate region of the bonding pad 321 and the second reduction potential +0.4 V formed in the intermediate region of the bonding pad 321. In other words, a reduction potential of a portion of the bonding pad 321 adjacent to the conductive pattern 233 may have a value between a reduction potential −0.4 V of a remaining portion of the bonding pad 321 and a reduction potential +0.4V of the remaining portion of the bonding pad 321.

In some embodiments, the outer conductive pattern 2333 may include Ti, Zn, V, and a combination thereof. Alternatively, the outer conductive pattern 2333 may include Ti, Zn, V, and a combination thereof.

In some embodiments, a third reduction potential may be formed in a lower region of the bonding pad 321 by a potential difference among the conductive plug PG, the conductive barrier layer BM, and the bonding pad 321 of FIG. 1B. In addition, a fourth reduction potential may be formed in the intermediate region of the bonding pad 321 by a potential difference between the conductive barrier layer BM and the bonding pad 321. The lower region of the bonding pad 321 may include an interface between the bonding pad 321 and the conductive barrier layer BM (i.e., a lower surface of the bonding pad 321), and the intermediate region of the bonding pad 321 may include a region of the bonding pad 321 excluding the interface between the bonding pad 321 and the conductive barrier layer BM (i.e., a region excluding the lower surface of the bonding pad 321). When the conductive plug PG includes, for example, copper, the third reduction potential and the fourth reduction potential may be substantially the same as each other.

The first thickness T1 of the conductive pattern may be within about 2 micrometers to about 4 micrometers, and alternatively, may be about 2.5 micrometers. The second thickness T2 of the outer conductive pattern 2333 may be about 0.01 micrometers to about 0.02 micrometers.

The third thickness T3 of the upper wiring layer 2311 may be within about 1 micrometer to about 2 micrometers, and alternatively, may be about 1.6 micrometers. The fourth thickness T4 of the lower wiring layer 2313 may be within about 1 micrometer to about 2 micrometers, and alternatively, may about 0.9 micrometers. The fifth thickness T5 of the bonding pad 321 may be within about 2 micrometers to about 3 micrometers, and alternatively, may be about 2.6 micrometers. In addition, a horizontal width W of the bonding pad 321 may be within about 7.5 micrometers to about 8.5 micrometers.

A dummy support substrate 400 may be arranged on the uppermost second semiconductor chip 200H. The dummy support substrate 400 may include, for example, a semiconductor material such as silicon (Si). In some embodiments, the dummy support substrate 400 may include only a semiconductor material. For example, the dummy support substrate 400 may be a portion of a bare wafer.

A support bonding insulating layer 330 may be positioned between the uppermost second semiconductor chip 200H and the dummy support substrate 400, and may be arranged to surround or at least partially surround a plurality of support bonding pads 341. The support bonding pad 341 may be at least partially surrounded by the support bonding insulating layer 330.

The support bonding insulating layer 330 may cover portions of an upper surface of the uppermost second semiconductor chip 200H and a lower surface of the dummy support substrate 400, which are not covered by the plurality of support bonding pads 341.

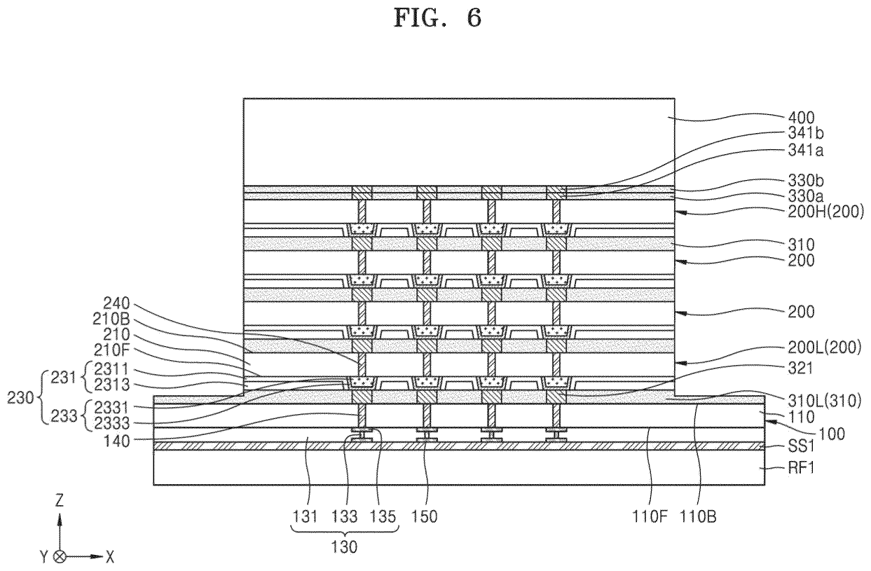

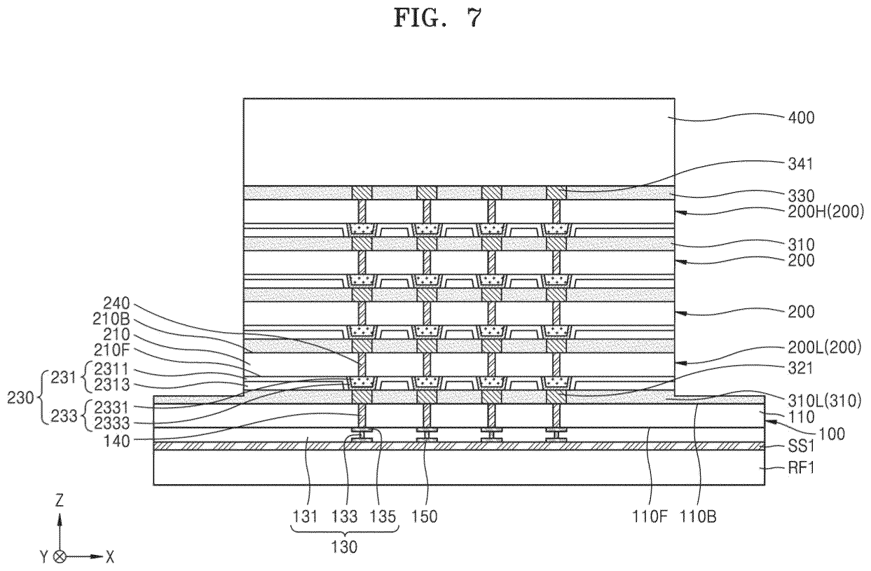

In some embodiments, the support bonding insulating layer 330 may be formed via diffusion bonding for respectively forming insulating material layers on the upper surface of the uppermost second semiconductor chip 200H and the lower surface of the dummy support substrate 400 facing each other, expanding the insulating material layers by heat to contact each other, and diffusing atoms within the insulating material layer such that the insulating material layers are integrated with each other. A method of forming the support bonding insulating layer 330 is described in detail below with reference to FIGS. 6 and 7.

The plurality of support bonding pads 341 may be positioned between the uppermost second semiconductor chip 200H and the dummy support substrate 400. The plurality of support bonding pads 341 may be arranged at locations corresponding to a plurality of second through electrodes 240 included in the uppermost second semiconductor chip 200H to be electrically connected to the plurality of second through electrodes 240 included in the uppermost second semiconductor chip 200H.

In some embodiments, the support bonding pad 341 may be formed via diffusion bonding for respectively forming conductive material layers on the upper surface of the uppermost second semiconductor chip 200H and the lower surface of the dummy support substrate 400 facing each other, expanding the conductive material layers by heat to contact each other, and diffusing metal atoms within the conductive material layers such that the conductive material layers are integrated with each other. The method of forming the support bonding pad 341 is described in detail below with reference to FIGS. 6 and 7.

In some embodiments, the support bonding insulating layer 330 may include the same material as the bonding insulating layer 310. For example, the support bonding insulating layer 330 may include a material capable of diffusion bonding. The support bonding insulating layer 330 may include any one of SiO, SiN, SiCN, SiCO, and a polymer material. The polymer material may be BCB, PI, PBO, silicon, acrylate, or epoxy. For example, the support bonding insulating layer 330 may include silicon oxide.

In some embodiments, the support bonding pad 341 may include the same material as the bonding pad 321. For example, the support bonding pad 341 may include a material capable of diffusion bonding, such as copper (Cu).

The semiconductor package 10 may include a package molding layer 500 covering a portion of the upper surface of the first semiconductor chip 100, which is not covered by the lowermost second semiconductor chip 200L. The package molding layer 500 may surround sidewalls of the plurality of second semiconductor chips 200 and a sidewall of the dummy support substrate 400. The package molding layer 500 may include, for example, an epoxy mold compound (EMC).

In some embodiments, the semiconductor package 10 may further include a base rewiring layer 600 arranged on the lower surface of the first semiconductor chip 100. The base rewiring layer 600 may include a package rewiring insulating layer 611, a plurality of package rewiring vias 613, and a package rewiring line pattern 615.

In some embodiments, a plurality of package rewiring insulating layers 611 may be stacked. The package rewiring insulating layer 611 may be formed from, for example, photo imagable dielectric (PID) or photosensitive polyimide (PSPI).

The package rewiring via 613 may be connected to the package rewiring line pattern 615 by extending through the package rewiring insulating layer 611. The package rewiring via 613 may be at least partially surrounded by the package rewiring insulating layer 611. In some embodiments, a plurality of package rewiring line patterns 615 may be stacked. The plurality of package rewiring line patterns 615 may be respectively arranged on the package rewiring insulating layers 611. In some embodiments, the plurality of package rewiring vias 613 may be formed together with the package rewiring line patterns 615 to be integrated therewith.

The package rewiring via 613 and the package rewiring line pattern 615 may include, for example, metal, such as copper (Cu), aluminum (Al), tungsten (W), titanium (Ti), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof, but are not limited thereto. In some embodiments, the package rewiring via 613 and the package rewiring line pattern 615 may be formed by stacking metal or an alloy of metal on a seed layer including titanium, titanium nitride, or titanium tungsten.

The plurality of package rewiring vias 613 and package rewiring line patterns 615 may be electrically connected to the plurality of chip pads 150. In some embodiments, at least some of the plurality of rewiring vias 613 may contact the plurality of chip pads 150. For example, when including the plurality of package rewiring insulating layers 611, the rewiring via 613, which extends through the uppermost package rewiring insulating layer 611, may contact the chip pad 150.

In some embodiments, the plurality of package rewiring vias 613 may have a tapered shape having a horizontal width decreasing from a lower side to an upper side. In other words, the plurality of package rewiring vias 613 may have the horizontal width increasing in a direction away from the first semiconductor chip 100.

A package pad 620 may be arranged on a lower surface of the base rewiring layer 600. In some embodiments, the package pad 620 may include the same material as the package rewiring line pad 615. A plurality of package pads 620 may be constructed, and the plurality of package pads 620 may respectively contact a plurality of package connection terminals 630. For example, the package connection terminal 630 may be a solder ball or a bump.

In some embodiments, the semiconductor package 10 may not include the base rewiring layer 600. For example, the plurality of package connection terminals 630 may be attached to the plurality of chip pads 150.

According to some embodiments, the outer conductive pattern 2333 may include a conductive material. However, as described above, a material constituting the outer conductive pattern 2333 may be limited such that the first reduction potential formed in the upper region of the bonding pad 321 is equal to or lower than the second reduction potential formed in the intermediate region of the bonding pad 321. In other words, the material constituting the outer conductive pattern 2333 may be limited such that a reduction potential of a portion of the bonding pad 321 adjacent to the conductive pattern 233 is equal to or lower than a reduction potential of a remaining portion of the bonding pad 321.

Alternatively, as described above, the material constituting the outer conductive pattern 2333 may be limited such that the first reduction potential formed in the upper region of the bonding pad 321 is equal to the second reduction potential formed in the intermediate region of the bonding pad 321 or has a difference of −0.4 V to 0.4 V therefrom. In other words, the material constituting the outer conductive pattern 2333 may be limited such that the reduction potential of the portion of the bonding pad 321 adjacent to the conductive pattern 233 is equal to the reduction potential of the remaining portion of the bonding pad 321 or has a difference of −0.4 V to +0.4 V therefrom.

As a comparative example, when a reduction potential formed in the upper surface of the bonding pad 321 by a potential difference among the inner conductive pattern 2331, the outer conductive pattern 2333, and the bonding pad 321 is higher than a reduction potential of a remaining region of the bonding pad 321 excluding the upper surface, which is formed by a potential difference between the outer conductive pattern 2333 and the bonding pad 321, corrosion of the inner conductive pattern 2331 and the outer conductive pattern 2333 may be promoted.

According to some embodiments, the material of the outer conductive pattern 2333 may be limited such that the first reduction potential formed in the upper region of the bonding pad 321 may be equal to or lower than the second reduction potential formed in the intermediate region of the bonding pad 321 or the first reduction potential formed in the upper region of the bonding pad 321 may be equal to the second reduction potential formed in the intermediate region of the bonding pad 321 or have a difference of −0.4 V to 0.4 V therefrom. Therefore, corrosion of the inner conductive pattern 23331 and the outer conductive pattern 2333 may be reduced, stripping between the conductive pattern 233 and the bonding pad 321 may be prevented, and ultimately, a semiconductor package having improved structural stability may be provided.

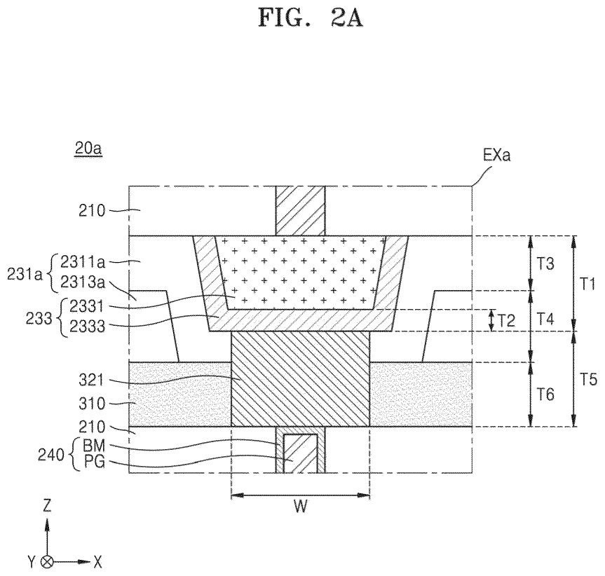

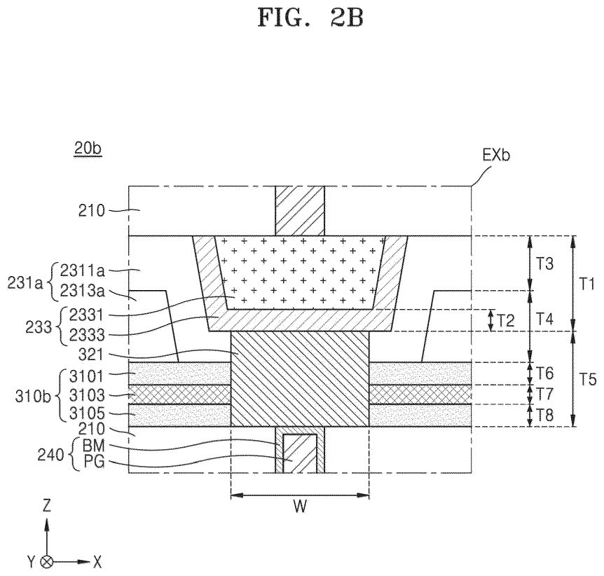

FIG. 2A is an enlarged view illustrating a semiconductor package 20a according to one or more example embodiments. That is, FIG. 2A illustrates an alternate view EXa of portion EX of FIG. 1A.

The semiconductor package 20a illustrated in FIG. 2A may be substantially the same as or similar to the semiconductor package 10 described with reference to FIGS. 1A and 1B, except that a second wiring layer 231a is included instead of the second wiring layer 231 of the semiconductor package 10 described with reference to FIGS. 1A and 1B. Hereinafter, differences from the semiconductor package 10 described with reference to FIGS. 1A and 1B are mainly described and repeated descriptions may be omitted.

Referring to FIG. 2A, the semiconductor package 20a may include a second wiring structure, and the second wiring structure may include the second wiring layer 231a and a plurality of conductive patterns 233 extending through a portion of the second wiring layer 231a. Each of the plurality of conductive patterns 233 may include an inner conductive pattern 2331 and an outer conductive pattern 2333 that covers a lower surface of the inner conductive pattern 2331 and conformally extends along a sidewall of the inner conductive pattern 2331 (i.e., the outer conductive patter 2333 may conformally cover a lower surface of the inner conductive pattern 2331).

The second wiring layer 231a may include an upper wiring layer 2311a and a lower wiring layer 2313a, and the upper wiring layer 2311a may conformally extend on a sidewall of the conductive pattern 233 to cover a lower surface of a second semiconductor substrate 210 and cover the sidewall of the conductive pattern 233 (i.e., the upper wiring layer 2311a may conformally cover a lower surface of a second semiconductor substrate 210 and the sidewall of the conductive pattern 233). The upper wiring layer 2311a may cover the sidewall of the conductive pattern 233, and may cover a portion of a lower surface of the conductive pattern 233, which is not covered by a bonding pad 321. The upper wiring layer 2311a may cover an upper portion of a sidewall of the bonding pad 321. The lower wiring layer 2313a may be arranged underneath the upper wiring layer 2311a. The lower wiring layer 2313a may fill a portion of a gap between a second semiconductor substrate 210 and a bonding insulating layer 310, which is not filled with the upper wiring layer 2311a.

The bonding insulating layer 310 may cover a lower portion of the sidewall of the bonding pad 321, which is not covered with the upper wiring layer 2311a. Accordingly, the sidewall of the bonding pad 321 may be surrounded by the upper wiring layer 2311a and the bonding insulating layer 310. An upper surface of the bonding insulating layer 310 may be spaced apart from the lower surface of the conductive pattern 233 with a lower portion of the upper wiring layer 2311a therebetween.

The first thickness T1 of the conductive pattern 233 may be within about 2 micrometers to about 4 micrometers, and alternatively, may be about 2.5 micrometers. The second thickness T2 outer conductive pattern 2333 may be about 0.01 micrometers to about 0.02 micrometers. The third thickness T3 of the upper wiring layer 2311a may be within about 1 micrometer to about 2 micrometers, and alternatively, may be about 1.6 micrometers. The fourth thickness T4 of the lower wiring layer 2313a may be within about 1 micrometer to about 3 micrometers. The fifth thickness T5 of the bonding pad 321 may be within about 2 micrometers to about 3 micrometers, and alternatively, may be about 2.6 micrometers. A horizontal width W of the bonding pad 321 may be within about 7.5 micrometers to about 8.5 micrometers. The sixth thickness T6 of the bonding insulating layer 310 may be within about 1 micrometer to about 2.5 micrometers.

FIG. 2B is an enlarged view illustrating a semiconductor package 20b according to embodiments. That is, FIG. 2B illustrates an alternate view EXb of portion EX of FIG. 1A.

The semiconductor package 20b illustrated in FIG. 2B may be substantially the same as or similar to the semiconductor package 10 described with reference to FIGS. 1A and 1B, except that a second wiring layer 231a is included instead of the second wiring layer 231 of the semiconductor package 10 described with reference to FIGS. 1A and 1B and a bonding insulating layer 310b is included instead of the bonding insulating layer 310 of the semiconductor package 10. Hereinafter, differences from the semiconductor package 10 described with reference to FIGS. 1A and 1B are mainly described and repeated descriptions may be omitted.

Referring to FIG. 2B, the semiconductor package 20b may include a second wiring structure, and the second wiring structure may include the second wiring layer 231a and a plurality of conductive patterns 233 extending through a portion of the second wiring layer 231a. Each of the plurality of conductive patterns 233 may include an inner conductive pattern 2331 and an outer conductive pattern 2333 that covers a lower surface of the inner conductive pattern 2331 and conformally extends along a sidewall of the inner conductive pattern 2331 (i.e., the outer conductive pattern 2333 may conformally cover a lower surface of the inner conductive pattern 2331 and a side wall of the inner conductive pattern 2331).

The second wiring layer 231a may include an upper wiring layer 2311a and a lower wiring layer 2313a, and the upper wiring layer 2311a may conformally extend on a sidewall of the conductive pattern 233 to cover a lower surface of a second semiconductor substrate 210 and cover the sidewall of the conductive pattern 233 (i.e., the upper wiring layer 2311a may conformally cover a lower surface of a second semiconductor substrate 210 and the sidewall of the conductive pattern 233). The upper wiring layer 2311a may cover the sidewall of the conductive pattern 233, and may cover a portion of a lower surface of the conductive pattern 233, which is not covered by a bonding pad 321. The upper wiring layer 2311a may cover an upper portion of a sidewall of the bonding pad 321. The lower wiring layer 2313a may be arranged underneath the upper wiring layer 2311a. The lower wiring layer 2313a may fill a portion of a gap between a second semiconductor substrate 210 and a bonding insulating layer 310, which is not filled with the upper wiring layer 2311a.

The bonding insulating layer 310b may cover a lower portion of the sidewall of the bonding pad 321, which is not covered with the upper wiring layer 2311a. Accordingly, the sidewall of the bonding pad 321 may be surrounded by the upper wiring layer 2311a and the bonding insulating layer 310b. An upper surface of the bonding insulating layer 310b may be spaced apart from a lower surface of the conductive pattern 233 with a lower portion of the upper wiring layer 2311a therebetween.

The bonding insulating layer 310b may have a multilayer structure. For example, the bonding insulating layer 310b may include a first insulating layer 3101, a second insulating layer 3103, and a third insulating layer 3105. However, the number of insulating layers, which may be included in the bonding insulating layer 310b, is not limited to three as illustrated, and one, two or four or more insulating layers may be included.

In some embodiments, the first insulating layer 3101 and the third insulating layer 3105 may include a nitride layer, and the second insulating layer 3103 may include an oxide layer. Materials constituting the first insulating layer 3101, the second insulating layer 3103, and the third insulating layer 3105 may be different from one another. For example, the first insulating layer 3101 may include a silicon nitride layer or a SiON layer, the second insulating layer 3103 may include a silicon oxide layer, an SiOC layer, or an SiCOH layer, and the third insulating layer 3105 may include a silicon nitride layer or an SiON layer. The terms “SiON”, “SiOC”, and “SiCOH” used herein refer to materials formed of elements included in the respective terms, and are not a chemical formula showing a stoichiometric relationship.

The sixth thickness T6 of the first insulating layer 3101, the seventh thickness T7 of the second insulating layer 3103, and the eighth thickness T8 of the third insulating layer 3105 may have a value within about 0.1 micrometer to about 1.5 micrometers.

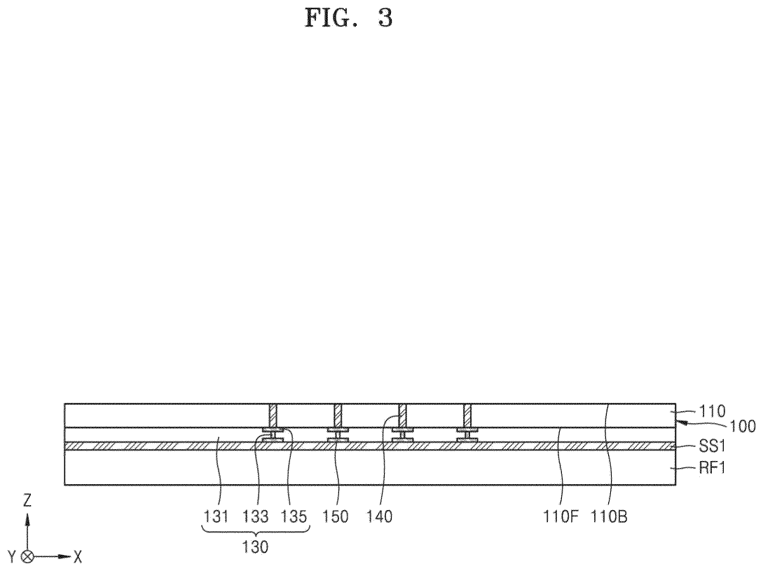

FIGS. 3, 4, 5, 6, 7, 8, 9, and 10 are cross-sectional views illustrating a method of manufacturing a semiconductor package 10, according to one or more embodiments.

Referring to FIG. 3, a first semiconductor chip 100 is attached onto a first support substrate SS1. The first semiconductor chip 100 may be attached onto a first release film RF1 after the first release film RF1 is attached to an upper surface of the first support substrate SS1. The first semiconductor chip 100 may be attached onto the first release film RF1 such that a first wiring structure 130 faces the first support substrate SS1. A plurality of chip pads 150, which are exposed on a lower surface of a first semiconductor substrate 110, may be attached to the first release film RF1.

Referring to FIG. 4, a plurality of first spare bonding pads 321a and a first spare bonding insulating layer 310a may be formed on an upper surface of the first semiconductor chip 100. The plurality of first spare bonding pads 321a may be arranged on the upper surface of the first semiconductor chip 100 (i.e., on an inactive surface of the first semiconductor substrate 110). The first spare bonding insulating layer 310a may be formed on the upper surface of the first semiconductor chip 100 to surround sidewalls of the plurality of first spare bonding pads 321a. The first spare bonding insulating layer 310a may cover the upper surface of the first semiconductor chip 100 and the sidewalls of the plurality of first spare bonding pads 321a, but may expose upper surfaces of the plurality of first spare bonding pads 321a without covering the upper surfaces thereof. The plurality of first spare bonding pads 321a may be arranged on the upper surface of the first semiconductor chip 100 to be connected to a plurality of first through electrodes 140.

The first spare bonding pad 321a may be formed by forming the first spare bonding insulating layer 310a, forming a plurality of first recesses by removing a portion of the first spare bonding insulating layer 310a, and filling insides of the plurality of first recesses with a conductive layer.

A plurality of second spare bonding pads 321b and a second spare bonding insulating layer 310b may be formed on a lower surface of a lowermost second semiconductor chip 200L. The second spare bonding insulating layer 310b may be formed on the lower surface of the lowermost second semiconductor chip 200L to surround sidewalls of the plurality of second spare bonding pads 321b. The second spare bonding insulating layer 310b may cover the lower surface of the lowermost second semiconductor chip 200L and the sidewalls of the plurality of second spare bonding pads 321b, but may expose lower surfaces of the plurality of second spare bonding pads 321b without covering the lower surfaces thereof. The plurality of second spare bonding pads 321b may be arranged on the lower surface of the lowermost second semiconductor chip 200L (i.e., on a lower surface of a second wiring structure 230). The plurality of second spare bonding pads 321b may be arranged on the lower surface of the lowermost second semiconductor chip 200L to be respectively connected to corresponding conductive patterns 233.

The second spare bonding pad 321b may be formed by forming the second spare bonding insulating layer 310b, forming a plurality of second recesses by removing a portion of the second spare bonding insulating layer 310b, and filling insides of the plurality of second recesses with a conductive material layer.

Referring to FIG. 5, by applying heat, pressure, or a combination thereof to the resultant structure of FIG. 4, the first spare bonding insulating layer 310a and the second spare bonding insulating layer 310b may be bonded to each other and the plurality of first spare bonding pads 321a may be bonded to the plurality of second spare bonding pads 321b. In some embodiments, the first spare bonding insulating layer 310a and the second spare bonding insulating layer 310b may be bonded to each other while forming a covalent bond, and the plurality of first spare bonding pads 321a and the plurality of second spare bonding pads 321b may be bonded to each other while forming covalent bonds.

In some embodiments, the lowermost second semiconductor chip 200L may be located on the first semiconductor chip 100, and heat at a first temperature may be applied thereto. Subsequently, by applying heat at a second temperature higher than the first temperature, a plurality of bonding pads 321 may be formed in which the plurality of first spare bonding pads 321a and the plurality of second spare bonding pads 321b corresponding to each other are coupled to each other, and a bonding insulating layer 310 may be formed in which the first spare bonding insulating layer 310a and the second spare bonding insulating layer 310b of FIG. 4 are coupled to each other.

The first spare bonding insulating layer 310a and the second spare bonding insulating layer 310b may contact each other, and then diffusion bonded to each other via diffusion of atoms to be integrated with each other, and accordingly, the bonding insulating layer 310 may be formed. Similarly, the plurality of bonding pads 321 may be formed by expanding, by heat, the plurality of first spare bonding pads 321a and the plurality of second spare bonding pads 321b corresponding to each other to contact each other, and then diffusion bonding the plurality of first spare bonding pads 321a and the plurality of second spare bonding pads 321b to each other via diffusion of metal atoms to be integrated with each other. Accordingly, the lowermost second semiconductor chip 200L may be attached onto the first semiconductor chip 100 through the plurality of bonding pads 321 and the bonding insulating layer 310.

A width of the first spare bonding insulating layer 310a on the upper surface of the first semiconductor chip 100 in a first horizontal direction (e.g., the X direction) may be substantially the same as a width of the first semiconductor chip 100 in the first horizontal direction (e.g., the X direction). A width of the second spare bonding insulating layer 310b on the lower surface of the lowermost second semiconductor chip 200L in the first horizontal direction (e.g., the X direction) may be substantially the same as a width of the lowermost second semiconductor chip 200L in the first horizontal direction (e.g., the X direction).

Accordingly, a portion of the first spare bonding insulating layer 310a on the upper surface of the first semiconductor chip 100, which overlaps the lowermost second semiconductor chip 200L, may form a lowermost bonding insulating layer 310L by contacting the second spare bonding insulating layer 310b on the lower surface of the lowermost second semiconductor chip 200L, and a remaining portion except the portion of the first spare bonding insulating layer 310a on the upper surface of the first semiconductor chip 100, which overlaps the lowermost second semiconductor chip 200L, may constitute a recess portion RS of the lowermost bonding insulating layer 310L without contacting the second spare bonding insulating layer 310b on the lower surface of the lowermost second semiconductor chip 200L.

Subsequently, as with the first spare bonding insulating layer 310a and the plurality of first spare bonding pads 321a formed on the upper surface of the first semiconductor chip 100 of FIG. 4, the first spare bonding insulating layer 310a and the plurality of first spare bonding pads 321a may be formed on the upper surface of the lowermost second semiconductor chip 200L and on upper surfaces of the remaining second semiconductor chips 200 except the uppermost second semiconductor chip 200H. The first spare bonding insulating layer 310a may be formed to surround side surfaces of the plurality of first spare bonding pads 321a, on the upper surface of the lowermost second semiconductor chip 200L. The first spare bonding insulating layer 310a may cover the lowermost second semiconductor chip 200L and side surfaces of the plurality of first spare bonding pads 321a, but may expose upper surfaces of the plurality of first spare bonding pads 321a without covering the upper surfaces thereof. The plurality of first spare bonding pads 321a may be arranged to be connected to a plurality of second through electrodes 240, on the upper surface of the lowermost second semiconductor chip 200L.

As with the first spare bonding pad 321a formed on the upper surface of the first semiconductor chip 100, the first spare bonding pad 321a formed on the upper surface of the lowermost second semiconductor chip 200L and the upper surfaces of the plurality of second semiconductor chips 200 may also be formed by forming the first spare bonding insulating layer 310a, forming a plurality of first recesses by removing a portion of the first spare bonding insulating layer 310a, and filling insides of the plurality of first recesses with a conductive material layer.

The second spare bonding insulating layer 310b and the plurality of second spare bonding pads 321b may be formed on lower surfaces of the plurality of second semiconductor chips 200 sequentially located on the lowermost second semiconductor chip 200L. The second spare bonding insulating layer 310b and the plurality of second spare bonding pads 321b may be formed even on the lower surface of the uppermost second semiconductor chip 200H.

As with the second spare bonding pad 321b formed on the lower surface of the lowermost second semiconductor chip 200L, the second spare bonding pad 321b may be formed by forming the second spare bonding insulating layer 310b, forming a plurality of second recesses by removing a portion of the second spare bonding insulating layer 310b, and filling insides of the plurality of second recesses with a conductive material layer.

Referring to FIG. 6, similarly to the above description in FIG. 5, between a plurality of second semiconductor chips 200, the bonding insulating layer 310 in which the first spare bonding insulating layer 310a and the second spare bonding insulating layer 310b are coupled to each other may be formed, and a plurality of bonding pads 321 in which the plurality of first spare bonding pads 321a and the plurality of second spare bonding pads 321b corresponding to each other are coupled to each other may be formed. The plurality of second semiconductor chips 200 may be sequentially attached onto the lowermost second semiconductor chip 200H through the bonding insulating layer 310 and the bonding pad 321.

A first spare support bonding insulating layer 330a and a first spare support bonding pad 341a may be formed on an upper surface of the uppermost second semiconductor chip 200H.

As with the first spare bonding pad 321a formed on the upper surface of the first semiconductor chip 100, the first spare support bonding pad 341a may be formed by forming the first spare support bonding insulating layer 330a, forming a plurality of first recesses by removing a portion of the first spare support bonding insulating layer 330a, and filling insides of the plurality of first recesses with a conductive material layer.

A second spare support bonding insulating layer 330b and a second spare support bonding pad 341b may be formed on a lower surface of a dummy support substrate 400, and then the dummy support substrate 400 may be located on the uppermost second semiconductor chip 200H. As with the second spare bonding pad 321b formed on the lower surface of the lowermost second semiconductor chip 200L, the second spare support bonding pad 341b may be formed by forming a second spare support bonding insulating layer 330b, forming a plurality of second recesses by removing a portion of the second spare support bonding insulating layer 330b, and filling insides of the plurality of second recesses with a conductive material layer.

The dummy support substrate 400 may be located on the uppermost second semiconductor chip 200H by using an edge of the uppermost second semiconductor chip 200H as an align key.

Referring to FIG. 7, similarly to the above description in FIG. 5, between the uppermost second semiconductor chip 200H and the dummy support substrate 400, a support bonding insulating layer 330 may be formed in which the first spare support bonding insulating layer 330a and the second spare support bonding insulating layer 330b are coupled to each other, and a plurality of support bonding pads 341 may be formed in which the plurality of first spare support bonding pads 341a and the plurality of second spare support bonding pads 341b corresponding to each other are coupled to each other. The dummy support substrate 400 may be attached onto the uppermost second semiconductor chip 200H through the support bonding insulating layer 330 and the plurality of support bonding pads 341.

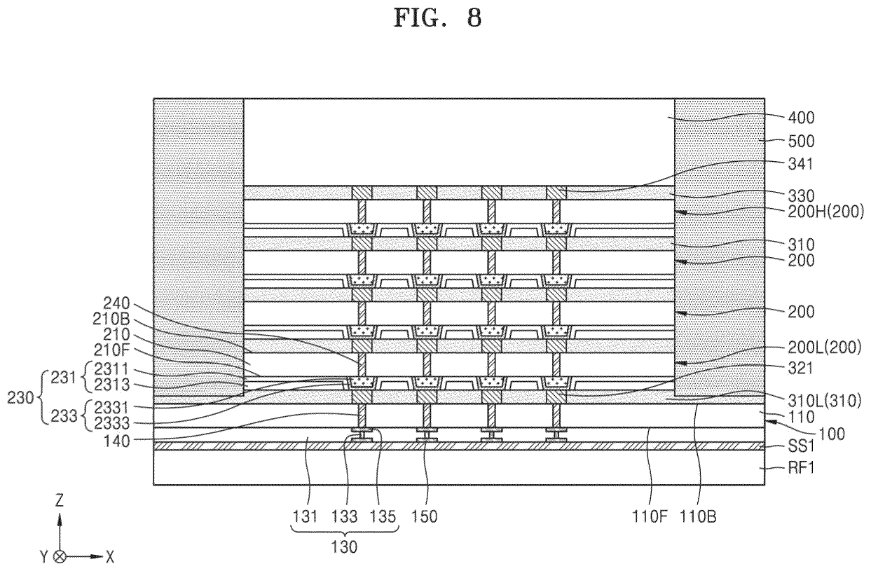

Referring to FIG. 8, a package molding layer 500 may be formed on the resultant structure of FIG. 7. In some embodiments, the package molding layer 500 may be formed to cover a sidewall of the dummy support substrate 400. In some embodiments, the package molding layer 500 may be formed to cover the sidewall and an upper surface of the dummy support substrate 400. A process of removing a portion of an upper portion of the dummy support substrate 400 and a portion of an upper portion of the package molding layer 500 by grinding may also be further performed to remove the package molding layer 500 formed on the upper surface of the dummy support substrate 400.

Accordingly, the package molding layer 500, which covers a portion of the upper surface of the first semiconductor chip 100 that is not covered by the lowermost second semiconductor chip 200L and surrounds the sidewalls of the plurality of second semiconductor chips 200 and the dummy support substrate 400, may be formed on the first semiconductor chip 100. After forming the package molding layer 500, the first support substrate SS1 onto which the first release film RF1 is attached, may be separated from the first semiconductor chip 100.

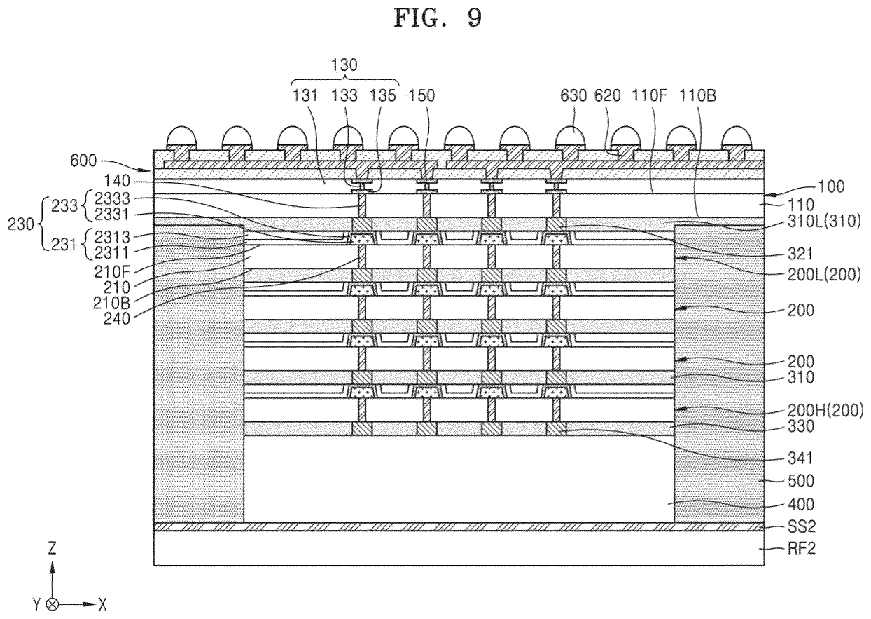

Referring to FIG. 9, the resultant structure of FIG. 8 may be turned over and then attached to a second support substrate SS2 onto which a second release film RF2 is attached. The second release film RF2 may be formed on an upper surface of the second support substrate SS2, and the dummy support substrate 400 and the package molding layer 500 may be attached onto an upper surface of the second release film RF2. According to some embodiments, the second release film RF2 may be omitted, and in this case, the dummy support substrate 400 and the package molding layer 500 may be attached onto the upper surface of the second support substrate SS2.

Subsequently, a base rewiring layer 600 may be formed on the first wiring structure 130 of the first semiconductor chip 100. The base rewiring layer 600 may include a package rewiring insulating layer 611, a plurality of package rewiring vias 613, and a plurality of package rewiring line patterns 615. At least some of the plurality of package rewiring vias 613 or at least some of the plurality of package rewiring line patterns 615 may be formed to contact the plurality of chip pads 150. From among the plurality of package rewiring line patterns 615, the package rewiring line pattern 615 arranged on an upper surface of the base rewiring layer 600 may form a package pad 620.

In some embodiments, the plurality of package rewiring vias 613 may be formed to have a tapered shape having a horizontal width increasing and extending from a lower side to an upper side.

Subsequently, a plurality of package connection terminals 630 may be respectively attached to a plurality of package pads 620. For example, the package connection terminal 630 may be a solder ball or a bump. The base rewiring layer 600 may be omitted according to the process. The plurality of package connection terminals 630 may be attached to the plurality of chip pads 150.

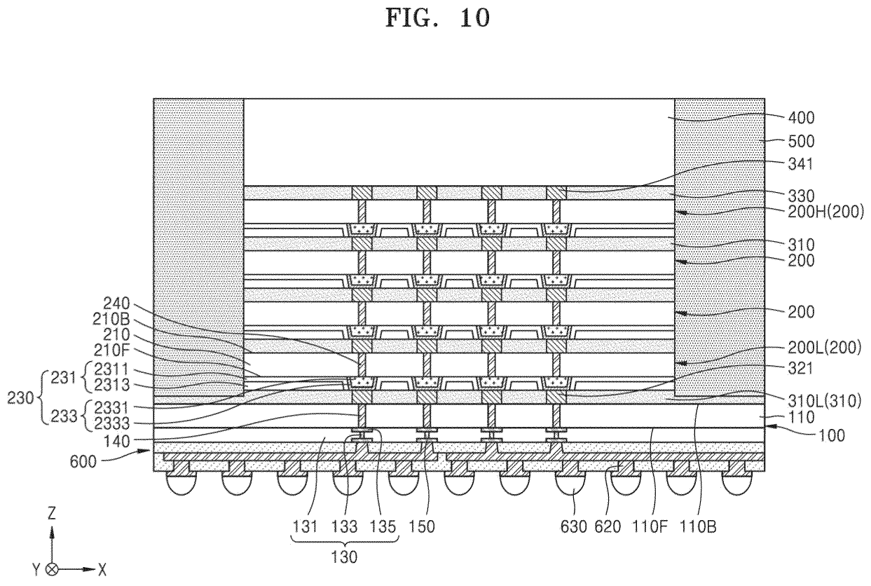

Referring to FIG. 10, the second support substrate SS2 having the second release film RF2 attached thereto may be separated from the resultant structure of FIG. 9, and the resultant structure, which is obtained by separating the second support substrate SS2 having the second release film RF2 attached thereto, may be turned over.

Subsequently, a process of dicing the resultant structure along a scribe lane may be performed to individualize the resultant structure into respective semiconductor packages.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a first semiconductor chip comprising a first semiconductor substrate, the first semiconductor substrate comprising an active surface and an inactive surface opposite to each other;
a plurality of second semiconductor chips stacked on the first semiconductor chip, each of the plurality of second semiconductor chips comprising a second semiconductor substrate comprising an active surface and an inactive surface opposite to each other;
a plurality of conductive patterns on the active surface of the second semiconductor substrate of each of the plurality of second semiconductor chips; and
a plurality of bonding pads on the inactive surface of the first semiconductor substrate and on the inactive surface of the second semiconductor substrate of each of the plurality of second semiconductor chips,
wherein the plurality of bonding pads are respectively connected to the plurality of conductive patterns,
wherein each of the plurality of conductive patterns comprises:
an inner conductive pattern; and
an outer conductive pattern comprising a portion between the inner conductive pattern and a respective bonding pad,
wherein the outer conductive pattern comprises a first metal that is ionized into an N-valent cation, N being a natural number of 1 or more, and
wherein a reduction potential of the first metal ionized into the N-valent cation is in a range from (−10×N) V to (−0.1567×N) V.

2. The semiconductor package of claim 1,
wherein the reduction potential of the first metal ionized into the N-valent cation is greater than (−0.9567V×N) V.

3. The semiconductor package of claim 1, wherein the inner conductive pattern comprises a first material, the outer conductive pattern comprises a second material, and the bonding pad comprises a third material, and
wherein the first material, the second material and the third material have different reduction potentials.

4. The semiconductor package of claim 1, wherein the inner conductive pattern comprises aluminum.

5. The semiconductor package of claim 1, wherein the bonding pad comprises copper.

6. The semiconductor package of claim 1, wherein the outer conductive pattern comprises Ti, V, or a combination thereof.

7. The semiconductor package of claim 1, wherein a horizontal width of each of the plurality of conductive patterns decreases from an upper side to a lower side.

8. The semiconductor package of claim 1, wherein a horizontal width of each of the plurality of conductive patterns is different with respect to a horizontal width of each of the plurality of bonding pads, such that sidewalls of the plurality of bonding pads are within the horizontal width of respective conductive patterns of the plurality of conductive patterns.

9. The semiconductor package of claim 1, wherein the outer conductive pattern conformally covers a lower surface and a sidewall of the inner conductive pattern.

10. The semiconductor package of claim 1, further comprising:
a plurality of bonding insulating layers at least partially surrounding the plurality of bonding pads; and
a plurality of wiring layers at least partially surrounding the plurality of conductive patterns,
wherein each of the plurality of wiring layers comprises an upper wiring layer and a lower wiring layer, and
wherein the upper wiring layer comprises a material different from a material of the lower wiring layer.

11. The semiconductor package of claim 10, wherein each upper wiring layer covers at least a portion of sidewalls of the plurality of bonding pads and at least a portion of sidewalls of the plurality of conductive patterns, and
wherein each lower wiring layer is spaced apart from the sidewalls of the plurality of conductive patterns.

12. The semiconductor package of claim 1, wherein the reduction potential of the first metal ionized into the N-valent cation is equal to or lower than (−0.5567×N) V.

13. A semiconductor package comprising:
a first semiconductor chip comprising a first semiconductor substrate and a plurality of first through electrodes extending through the first semiconductor substrate, the first semiconductor substrate comprising an active surface and an inactive surface opposite to each other;
a plurality of second semiconductor chips stacked on the first semiconductor chip, each of the plurality of second semiconductor chips comprising a second semiconductor substrate and a plurality of second through electrodes extending through the second semiconductor substrate comprising an active surface and an inactive surface opposite to each other;
a plurality of conductive patterns on the active surface of the second semiconductor substrate of each of the plurality of second semiconductor chips; and
a plurality of bonding pads on the plurality of first through electrodes and the plurality of second through electrodes,
wherein the plurality of bonding pads are respectively electrically connected between the plurality of first through electrodes and the plurality of conductive patterns, and between the plurality of second through electrodes and the plurality of conductive patterns,
wherein each of the plurality of conductive patterns comprises a first metal that is ionized into an N-valent cation, N being a natural number of 1 or more, and
wherein a reduction potential of the first metal ionized into the N-valent cation is in a range from (−0.9567×N) V to (−0.1567×N) V.

14. The semiconductor package of claim 12, wherein the reduction potential of the first metal ionized into the N-valent cation is equal to or lower than (−0.5567×N) V.

15. The semiconductor package of claim 12, wherein the outer conductive pattern comprises Ti, V, Zn, or a combination thereof.

16. The semiconductor package of claim 12, wherein a horizontal width of each of the plurality of conductive patterns is different with respect to a horizontal width of each of the plurality of bonding pads, such that sidewalls of the plurality of bonding pads are within the horizontal width of respective conductive patterns of the plurality of conductive patterns.

17. A semiconductor package comprising:
a first semiconductor chip comprising a first semiconductor substrate and a plurality of first through electrodes extending through the first semiconductor substrate, the first semiconductor substrate comprising an active surface and an inactive surface opposite to each other;
a plurality of second semiconductor chips stacked on the first semiconductor chip, each of the plurality of second semiconductor chips comprising a second semiconductor substrate and a plurality of second through electrodes extending through the second semiconductor substrate, wherein the second semiconductor substrate of each of the plurality of second semiconductor chips comprises an active surface and an inactive surface opposite to each other;
a plurality of conductive patterns on the active surface of the second semiconductor substrate of each of the plurality of seconds semiconductor chips, the plurality of conductive patterns comprising aluminum; and
a plurality of bonding pads on the inactive surface of the first semiconductor substrate and the inactive surface of the second semiconductor substrate of each of the plurality of second semiconductor chips,
wherein the plurality of bonding pads are respectively connected to the plurality of conductive patterns,
wherein each of the plurality of conductive patterns comprises:
an inner conductive pattern comprising copper; and
an outer conductive pattern covering a sidewall of the inner conductive pattern and a lower surface of the inner conductive pattern,
wherein the outer conductive pattern comprises a first metal that is ionized into an N-valent cation, N being a natural number of 1 or more, and
wherein a reduction potential of the first metal ionized into the N-valent cation is in a range of (−0.9567×N) V to (−0.1567×N) V.

18. The semiconductor package of claim 17, wherein the outer conductive pattern comprises Ti, V, Zn, or a combination thereof.

19. The semiconductor package of claim 17, wherein the reduction potential of the first metal ionized into the N-valent cation is equal to or lower than (−0.5567×N) V.

20. The semiconductor package of claim 17, further comprising:
a plurality of bonding insulating layer at least partially surrounding the plurality of bonding pads; and
a plurality of wiring layers at least partially surrounding the plurality of conductive patterns,
wherein each of the plurality of wiring layers comprises an upper wiring layer and a lower wiring layer, and
wherein the upper wiring layer comprises a material different from a material of the lower wiring layer.
